(19) United States
(12) Patent Application Publication
(10) Pub. No.: US 2009/0142899 A1
(43) Pub. Date: Jun. 4, 2009

(54) INTERFACIAL LAYER FOR HAFNIUM-BASED HIGH-K/METAL GATE TRANSISTORS

(76) Inventors: Jacob M. Jensen, Beaverton, OR (US); Huicheng Chang, Beaverton, OR (US)

Correspondence Address: RAHUL D. ENGINEER;Intel Corporation, c/o Intellevate, LLC, P.O. Box 52050, Minneapolis, MN, 55402, US

(21) Appl. No.: 11/949,775

(22) Filed: Dec. 4, 2007

(51) Int. Cl. H01L 21/336; H01L 21/283; H01L 21/31

(52) U.S. Cl. 438/287; 438/589; 438/769; 257/E21.423; 257/E21.211; 257/E21.18

(57) ABSTRACT

A method of forming an interfacial layer for hafnium-based high-k/metal gate transistors comprises depositing a hafnium-based high-k dielectric layer on a semiconductor substrate and then annealing the high-k dielectric layer and the semiconductor substrate in a nitric oxide atmosphere for a time duration and at a temperature sufficient to drive at least a portion of the nitric oxide through the dielectric layer to an interface between the dielectric layer and the substrate. At this interface, the nitric oxide reacts with the substrate to form a silicon oxynitride interfacial layer.

### BACKGROUND

To fabricate transistors at the 45 nanometer (nm) node and below, modern processes use high-k dielectric materials for the gate dielectric layer along with metals other than polysilicon for the gate electrode. Such devices may be referred to as high-k/metal gate transistors. The high-k gate dielectric layer is generally deposited directly on a silicon substrate and a metal gate electrode is formed on the high-k gate dielectric layer. The metal gate electrode may be formed using a subtractive or a replacement metal gate process, as is known in the art.

During fabrication of the high-k/metal gate transistor, an interfacial layer often forms between the substrate and the high-k gate dielectric layer. The interfacial layer is essentially a poor quality silicon oxynitride layer that arises from the wet cleans that occur on the silicon substrate prior to the high-k deposition. When a hafnium-based high-k dielectric is used, the quality of the interface between the interfacial layer and the hafnium layer is very poor. As a result, the reliability of the transistor may suffer. In addition, the thickness of this interfacial layer is difficult to control since the layer is not intentionally engineered.

In some processes, the interfacial layer may be intentionally grown to ensure that a higher quality silicon oxynitride is provided. The issues that arise with this solution are queue time constraints and possible contamination or oxidation of the interfacial layer. In addition, controlling the thickness of the silicon oxynitride by thermal oxidation prior to high-k deposition can add extra process complexity. Better solutions are therefore desired.

### BRIEF DESCRIPTION OF THE DRAWINGS

FIG. 1 is a process flow for fabricating a high-quality interfacial layer between a hafnium-based high-k gate dielectric layer and a substrate in accordance with an implementation of the invention.

FIGS. 2 through 8 illustrate the process flow that is described in FIG. 1.

FIGS. 9 through 12 illustrate a replacement metal gate process flow in accordance with another implementation of the invention.

### DETAILED DESCRIPTION

Described herein are systems and methods of forming a high quality interfacial layer between a substrate and a hafnium-based high-k gate dielectric layer. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a process for fabricating a high-quality interfacial layer between a substrate and a high-k gate dielectric layer for a high-k/metal gate transistor, including but not limited to a hafnium-based dielectric layer. In implementations of the invention, the growth of this interfacial layer may be precisely engineered through the use of an annealing process in a nitric oxide ambient. In implementations of the invention, the high-quality interfacial layer may be formed at a thickness that ranges from 1 Angstrom (Å) to 20 Å for various device applications. The quality of the interfacial layer addresses both the device performance and reliability issues.

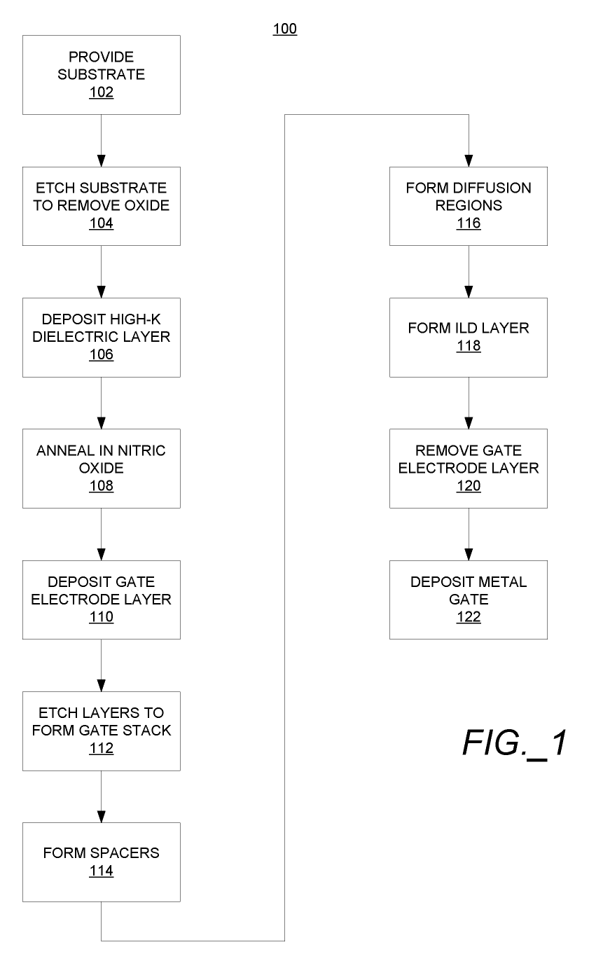

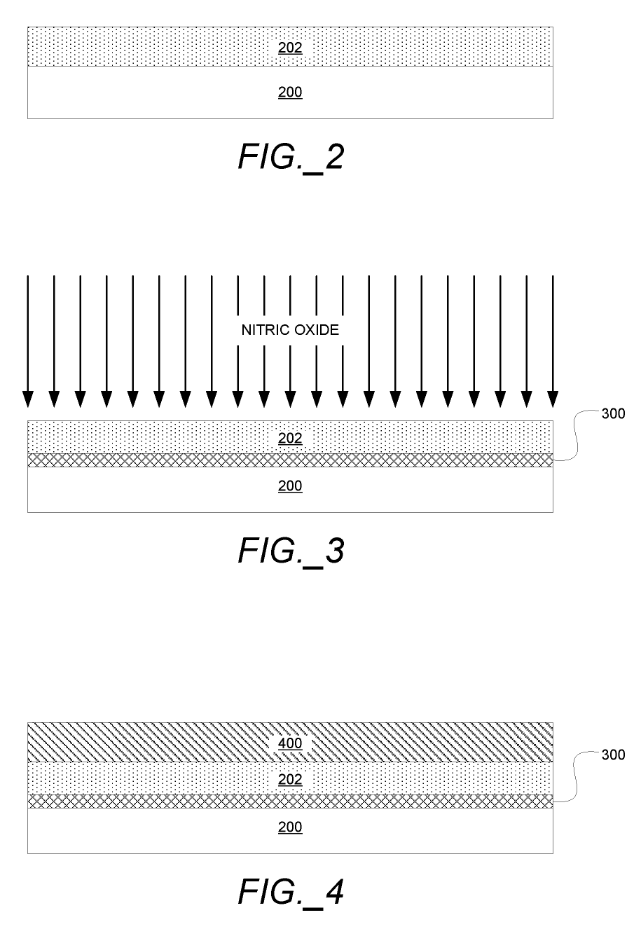

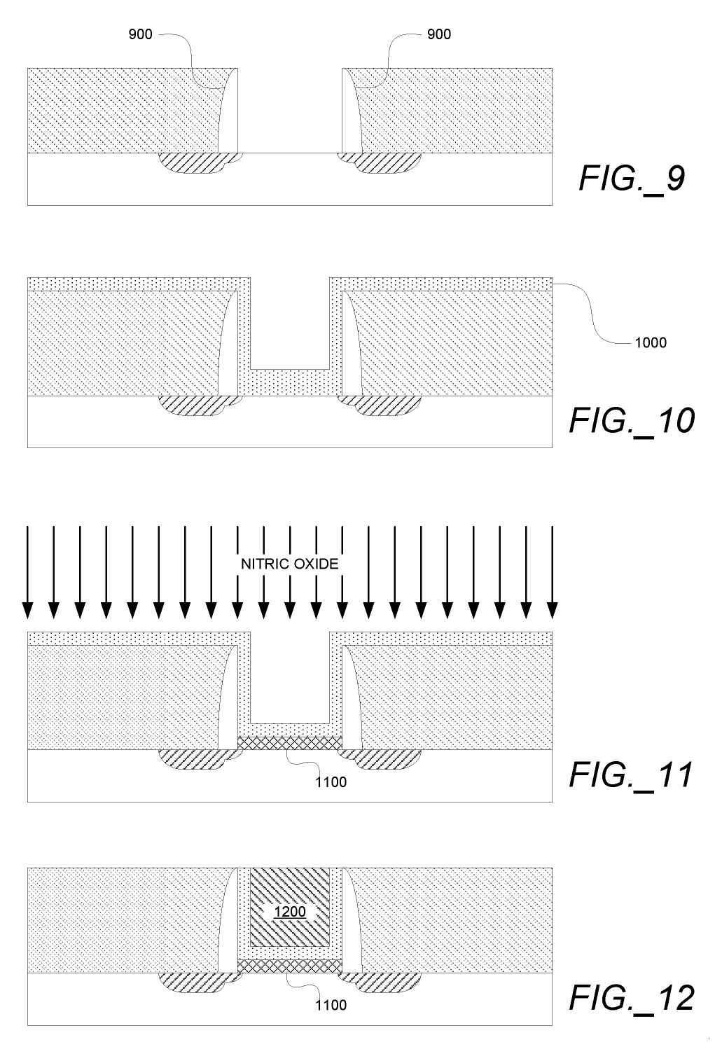

FIG. 1 is a process flow 100 for fabricating a high-quality interfacial layer between a hafnium-based gate dielectric layer and a semiconductor substrate in a high-k/metal gate MOS transistor. It should be noted that although a hafnium-based gate dielectric layer is used in this exemplary implementation, in alternate implementations other high-k gate dielectric materials may be used. FIGS. 2 through 8 illustrate the process flow 100 that is described in FIG. 1. It should be noted that while the process described in FIG. 1 and shown in FIGS. 2 through 8 provides a subtractive process for forming the gate stack of the high-k/metal gate MOS transistor, the process flow may be used in a replacement metal gate process as well, as shown in FIGS. 9 through 12.

The process flow 100 begins by providing a semiconductor substrate upon which the high-k/metal gate transistor may be formed (process 102 of FIG. 1). The semiconductor substrate may be formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

An etching process is carried out on the substrate to remove any native oxide, such as silicon oxide, that may have formed on the semiconductor substrate (104). Conventional wet or dry etching processes known in the art for removing oxide from a substrate may be used, such as a hydrofluoric acid application. The semiconductor substrate may remain in an oxygen-free atmosphere to prevent oxidation of the surface.

A high-k gate dielectric layer is deposited on the substrate (106). The high-k gate dielectric material may be formed from a hafnium-based material, such as hafnium oxide (HfO₂). As mentioned above, alternate high-k materials may be in lieu of hafnium oxide, including but not limited to hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, a thickness of the high-k gate dielectric layer may fall between around 5 Angstroms (Å) and around 30 Å. In further embodiments, additional processing may be performed on the high-k gate dielectric layer, such as an annealing process to improve the quality of the high-k material. The high-k dielectric layer may be deposited using processes known in the art, including but not limited to a chemical vapor deposition (CVD) process, an atomic layer deposition (ALD) process, and a physical vapor deposition (PVD) process such as sputtering.

FIG. 2 illustrates a semiconductor substrate 200 and a high-k gate dielectric layer 202 is formed on the substrate 200.

Next, in accordance with an implementation of the invention, an interfacial layer is formed by subjecting the substrate and the high-k gate dielectric layer to an annealing process in a nitric oxide (NO) ambient (108). The annealing process causes nitric oxide molecules to diffuse through the high-k dielectric layer and react with silicon at the interface between the substrate and the dielectric layer. The reaction yields a silicon oxynitride layer at this interface. The silicon oxynitride layer generally has an oxygen-to-nitrogen ratio of around 10-to-1.

In various implementations, the annealing process may be carried out using a furnace annealing technique or a rapid thermal anneal technique (i.e., a spike anneal). The anneal may be carried out at a temperature that falls between 300° C. and 1200° C. and for a time duration that ranges from approximately one second up to approximately 180 seconds. For instance, given a HfO₂ dielectric layer with a thickness of 20 Å, in one implementation of the invention a furnace anneal may be used at a temperature around 700° C. for a time duration of around 60 seconds to produce an interfacial layer that is around 11 Å thick. In another implementation, given the same 20 Å dielectric layer, a rapid thermal anneal may be used at a temperature around 1000° C. for approximately one second to produce an interfacial layer that is around 15 Å thick.

In an implementation of the invention, the ambient atmosphere consists of pure nitric oxide (i.e., 100% NO). In alternate implementations, the ambient atmosphere may have a nitric oxide concentration that is less than 100%.

A thickness of the interfacial layer will generally depend on the anneal process parameters. The interfacial layer thickness may be precisely controlled by manipulating parameters such as the peak anneal temperature, the time duration used, and the nitric oxide concentration in the ambient. In various implementations of the invention, the thickness of the interfacial layer that is formed may range from 1 Å to 20 Å.

The annealing process is illustrated in FIG. 3. The ambient atmosphere contains nitric oxide molecules that penetrate the high-k gate dielectric layer 202 and react with silicon in the substrate 200 to form an interfacial layer 300.

The process flow 100 may now continue with conventional CMOS fabrication techniques to incorporate the hafnium-based high-k gate dielectric layer and the interfacial layer into a metal-oxide-semiconductor field effect transistor (MOSFET). For example, a metal gate electrode layer or a sacrificial gate electrode layer may be deposited atop the high-k dielectric layer for use in a subtractive or replacement metal gate process (110). If a metal gate electrode is used, the metal must consist of polysilicon or another conductive material that is able to withstand all of the annealing processes used, such as the anneals form the diffusion regions. If a sacrificial gate electrode layer is used, the layer may comprise a material such as polysilicon, silicon nitride, or any other material that is compatible with high temperature annealing processes used to form diffusion regions (e.g., a source region and a drain region) during fabrication of the CMOS device. The metal or sacrificial gate electrode layer may be deposited using a CVD process or a PVD process such as sputtering.

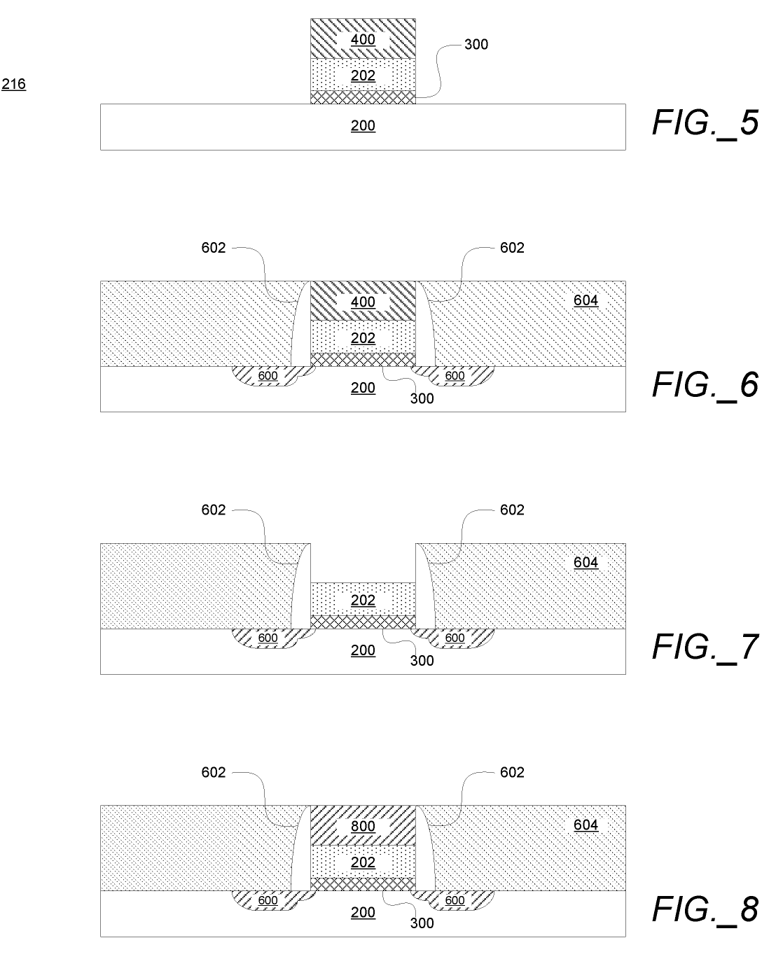

FIGS. 4 through 8 illustrate one fabrication process for a MOSFET. FIG. 4 illustrates the deposition of a metal or sacrificial gate electrode layer 400 on the dielectric layer 202. Next, the layers on the substrate may be patterned to form a gate stack on the substrate (112). Conventional patterning processes may be used here. For instance, one patterning process begins by depositing a photoresist material over the sacrificial layer and patterning the photoresist using ultraviolet radiation and an optical mask to define features such as the gate stack in the resist layer. The photoresist layer is developed to form a photoresist mask that protects the defined features, such as the portion of the underlying layers that will form the gate stack. An etchant is then applied to remove unprotected portions of the underlying layers, yielding a patterned gate stack as shown in FIG. 5.

After the gate stack is formed, tip regions, diffusion regions, a pair of spacers, and an ILD layer are formed on the substrate. The spacers may be formed adjacent to the gate stack by depositing a material, such as silicon nitride or silicon dioxide, on the substrate and then etching the material to form the pair of spacers (114). After the spacers are formed, an ion implantation process may be used to implant dopants, such as boron, phosphorous, or arsenic, into the substrate adjacent the spacers to form diffusion regions and tip regions (116). An annealing process may follow the ion implantation process to drive the dopants further into the substrate and/or to activate the dopants. Alternately, the diffusion regions may be formed by etching regions of the substrate and epitaxially depositing a silicon or silicon-germanium based material into the etched regions to form the diffusion regions. These diffusion regions function as source and drain regions for the CMOS device.

Finally, a low-k dielectric material may be deposited and polished to form an ILD layer over the device (118). Low-k dielectric materials that may be used for the ILD layer include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layer may include pores or other voids to further reduce its dielectric constant. FIG. 6 illustrates the formation of diffusion regions 600 having tip regions, spacers 602, and an ILD layer 604 on the substrate 200.

If the gate electrode layer 400 is formed of a metal gate electrode material, the gate stack may remain as is. Alternately, if the gate electrode layer 400 is formed of a sacrificial gate electrode material, a replacement metal gate process may now be carried out to replace the sacrificial material with a metal gate electrode. In one implementation, the sacrificial gate electrode may be removed using conventional wet or dry etching processes (120). Such etching processes are well known in the art. FIG. 7 illustrates removal of the sacrificial layer 400, thereby causing a trench to be formed between the spacers 602.

A metal gate electrode may be deposited into this trench (122). Conventional metal deposition processes may be used, such as ALD, CVD, PVD, electroless plating, or electroplating processes. A planarization process such as CMP may be used to remove excess deposited metal. The metal gate electrode may be formed using any conductive material from which a metal gate electrode may be derived including pure metals, metal alloys, metal oxides, nitrides, oxynitrides, and carbides.

When the metal gate electrode will serve as an N-type workfunction metal, the gate electrode preferably has a workfunction that is between about 3.9 eV and about 4.2 eV. N-type materials that may be used to form the metal gate electrode include, but are not limited to, hafnium, zirconium, titanium, tantalum, aluminum, and metal carbides that include these elements, i.e., titanium carbide, zirconium carbide, tantalum carbide, hafnium carbide and aluminum carbide.

When the metal gate electrode will serve as a P-type workfunction metal, the gate electrode preferable has a workfunction that is between about 4.9 eV and about 5.2 eV. P-type materials that may be used to form the metal gate electrode include, but are not limited to, ruthenium, palladium, platinum, cobalt, nickel, and conductive metal oxides, e.g., ruthenium oxide.

The metal gate electrode should be thick enough to ensure that any material formed on it will not significantly impact its workfunction. Preferably, the metal gate electrode is between about 25 angstroms (Å) and about 600 Å thick, and more preferably is between about 50 Å and about 200 Å thick. Although a few examples of materials that may be used to form the metal gate electrode are described here, that layer may be made from many other materials.

FIG. 8 illustrates the formation of a metal gate electrode 800 on the gate dielectric layer 202. The metal gate electrode 800 is formed of a P-type or an N-type workfunction metal. In some implementation, the metal gate electrode 800 may include at least two layers, one layer functioning as a workfunction metal layer and the second layer functioning as a fill metal layer.

FIGS. 9 to 12 illustrate a process flow for using the invention in another replacement metal gate process. FIG. 9 begins by illustrating a trench formed between a pair of spacers 900 after a dummy gate dielectric and a dummy gate electrode have been etched away. Methods of arriving at this structure are well known in the art. The surface of the substrate at the bottom of the trench has also been etched to remove any native oxide. Moving to FIG. 10, a hafnium-based high-k gate dielectric layer 1000 is deposited in the trench.

Turning to FIG. 11, an annealing process is carried out in a nitric oxide ambient to cause an interfacial layer 1100 to form at the interface between the high-k dielectric layer and the substrate. The annealing parameters described above may be used here.

Finally, turning to FIG. 12, a metal gate electrode 1200 may be deposited on the high-k gate dielectric layer. As described above, a P-type or an N-type metal may be used to form the metal gate electrode 1200, and in some implementations, the metal gate electrode 1200 may include a workfunction metal layer and a fill metal layer. A planarization process may also be used to remove excess metal sited atop the ILD layer.

Accordingly, a process flow has been described for fabricating a MOS transistor with an improved interfacial layer between the hafnium-based high-k gate dielectric layer and the semiconductor substrate. As described above, the process flow of the invention enables precise thickness control of the interfacial silicon oxynitride transition layer by varying the annealing parameters. Issues such as queue time constraints are eliminated and the interfacial layer is immune to ambient contamination and/or room temperature oxidation.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
depositing a high-k dielectric layer on a semiconductor substrate; and
annealing the high-k dielectric layer and the semiconductor substrate in a nitric oxide atmosphere for a time duration and at a temperature sufficient to drive at least a portion of the nitric oxide through the dielectric layer to an interface between the dielectric layer and the substrate, wherein the nitric oxide reacts with the substrate to form a silicon oxynitride interfacial layer.

2. The method of claim 1, wherein the high-k dielectric layer comprises hafnium oxide.

3. The method of claim 1, wherein the time duration is a time duration that ranges from approximately one second up to approximately 180 seconds.

4. The method of claim 1, wherein the temperature is a temperature that falls between around 300° C. and around 1200° C.

5. The method of claim 1, wherein the time duration is around 60 seconds and the temperature is around 700° C.

6. The method of claim 1, wherein the time duration is approximately one second and the temperature is around 1000° C.

7. A method comprising:
depositing a high-k dielectric layer on a semiconductor substrate;
annealing the high-k dielectric layer and the semiconductor substrate in a nitric oxide atmosphere for a time duration and at a temperature sufficient to drive at least a portion of the nitric oxide through the dielectric layer to an interface between the dielectric layer and the substrate, wherein the nitric oxide reacts with the substrate to form a silicon oxynitride interfacial layer;
depositing a sacrificial layer on the high-k dielectric layer;
etching the sacrificial layer, the high-k dielectric layer, and the interfacial layer to form a gate stack;
forming a pair of spacers on laterally opposite sides of the gate stack;
forming diffusion regions in the substrate adjacent to the spacers;
forming an ILD layer on the substrate;
removing the sacrificial layer to form a trench between the spacers; and
depositing a metal gate electrode layer in the trench.

8. The method of claim 7, wherein the high-k dielectric layer comprises hafnium oxide.

9. The method of claim 7, wherein the time duration is a time duration that ranges from approximately one second up to approximately 180 seconds.

10. The method of claim 7, wherein the temperature is a temperature that falls between around 300° C. and around 1200° C.

11. The method of claim 7 wherein the time duration is around 60 seconds and the temperature is around 700° C.

12. The method of claim 7, wherein the time duration is less than 1 second and the temperature is around 1000° C.

13. A method comprising:
providing a semiconductor substrate having a pair of spacers and an ILD layer, wherein a trench is situated between the pair of spacers exposing a portion of the substrate;
depositing a high-k dielectric layer on the exposed substrate within the trench;
annealing the high-k dielectric layer and the substrate in a nitric oxide atmosphere for a time duration and at a temperature sufficient to drive at least a portion of the nitric oxide through the dielectric layer to an interface between the dielectric layer and the substrate, wherein the nitric oxide reacts with the substrate to form a silicon oxynitride interfacial layer; and
depositing a metal gate electrode layer in the trench.

14. The method of claim 13, wherein the high-k dielectric layer comprises hafnium oxide.

15. The method of claim 13, wherein the time duration is a time duration that ranges from approximately one second up to approximately 180 seconds and wherein the temperature is a temperature that falls between around 300° C. and around 1200° C.
